(19) United States
(12) Patent Application Publication
(10) Pub. No.: US 2026/0194086 A1
(43) Pub. Date: Jul. 9, 2026

(54) AUTOMATIC POSITIONING AND STEPLESS UNLOCKING FIXING DEVICE

(71) Applicant: HANWIT PRECISION INDUSTRIES LTD., New Taipei City (TW)

(72) Inventors: Ying-Chih TSENG, New Taipei City (TW); Ming-De WU, New Taipei City (TW)

(21) Appl. No.: 19/009,287

(22) Filed: Jan. 3, 2025

(51) Int. Cl. F16B 2/18

(52) U.S. Cl. CPC F16B 2/185

(57) ABSTRACT

An automatic positioning and stepless unlocking fixing device includes a base having a top panel, a bottom panel, two side panels, a receiving cavity, two opposite through holes, an actuating opening; a spring plate fixed to the top and providing a contact portion and an engaging block; a lever having a cam portion for engagement of the engaging block, an operating portion, an elastic member provided between the cam portion and the pivoting structure of the base and an abutment structure with a locking area, a buffer area and an unlocking area and the locking area and the buffer area being structured in a gradually expanding arc face from top to bottom; and a support including a positioning plate and an abutting rod with a contact surface on the top and an interference portion with a larger width and a locking portion with a smaller width on the periphery.

### BACKGROUND OF THE INVENTION

### 1. Field of the Invention

The present invention relates to an automatic positioning and stepless unlocking fixing device, particularly a fixing device that when the contact portion of the spring plate of the fixing device is located at the unlocking area of the lever, the spring plate is flatly attached to the top panel of the base, the engaging block and the cam portion are locked and positioned, and the elastic member is in a compressed state, a fully unlocked state is formed; the contact surface of the abutting rod can push the contact portion of the spring plate upward and lift the spring plate upward, causing the engaging block of the spring plate to separate from the contact with the cam portion, and the elastic member to form an elastic reset state and cause the lever to rotate, so that the interference portion and the locking portion of the abutting rod slightly interfere with the buffer area at the same time to form a buffer unlocked state; when the interference portion and the locking portion of the abutting rod are simultaneously pressed against the locking area, a fully locked state is formed. By the above, the purpose of one-time locking of the fixing device and the stepless buffer unlocking is achieved to prevent the fixing device from being damaged due to instantaneous rotation resistance stress.

### 2. Description of the Related Art

With the rapid development of industrial technology, various industrial products such as computers, televisions, telephones, refrigerators, washing machines, wardrobes, drawers or desks have long become indispensable items in people's lives. The aforementioned industrial products are mostly composed of multiple components, such as the computer housing, the circuit board and the heat sink inside the TV housing, the desk panel and supporting side panels, etc., and most of the components are assembled together by locking with screws. The industrial products can be disassembled into multiple components for easy transportation, and then the assembled industrial products can be partially disassembled for maintenance or replacement.

Furthermore, since the components of the aforementioned industrial products are assembled and combined with each other by means of screw locking, when assembling the components of the industrial products, the components whose surfaces are pressed by the heads of the screws are often damaged by being screwed too tightly, such as being dented or broken. In order to solve the aforementioned problem of component damage caused by screw locking, some manufacturers also use welding to assemble the components. However, this design will make it difficult to disassemble some components of the assembled industrial product, thereby causing difficulties in repairing or replacing components.

Therefore, how to solve the various problems caused by the assembly methods of the components of the aforementioned industrial products is the direction that the relevant manufacturers engaged in this industry are eager to study and improve.

### SUMMARY OF THE INVENTION

Therefore, in view of the above problems and deficiencies, the inventor collected relevant information and, after multiple evaluations and considerations, designed the invention of this automatic positioning and stepless unlocking fixing device.

The main object of the present invention is to provide an automatic positioning and stepless unlocking fixing device, which comprises a base, a spring plate, a lever and a support. The base comprises a top panel, a bottom panel, two opposite side panels, a receiving cavity surrounded by the top panel, the bottom panel and the side panels, a through hole provided in each of the top panel and the bottom panel, and an actuating opening formed in one side panel in communication with the receiving cavity. The spring plate has one end thereof fixed to the top panel of the base. The spring plate comprises a contact portion located at an opposite end thereof and extending downward into the through hole, and an engaging block extending from the bottom surface thereof into the receiving cavity. The lever comprises a cam portion pivotally connected between the top panel and the bottom panel of the base and received in the receiving cavity, an elastic member provided between the cam portion and the pivoting structure of the base pivoting with the cam portion, a structure formed on a top side of the cam portion for the engaging block of the spring plate to engage and position, an operating portion extending from the cam portion and located at the actuating opening, and an abutment structure formed on an opposite side of the cam portion relative to the operating portion. The abutment structure comprises a locking area located on one side, a buffer area located in the center and a vertical unlocking area formed on one side of the buffer area opposite to the locking area. The locking area and the buffer area are formed into a gradually expanding arc surface structure from top to bottom. The support comprises a positioning plate, an abutting rod protruding upward from the positioning plate and being capable of extending into the through hole of the base and entering into the receiving cavity, a contact surface formed on the top side of the abutting rod, an interference portion with a relatively larger width formed on an upper side of the abutting rod, and a locking portion with a relatively smaller width formed on a lower side of the abutting rod. According to the above, when the contact portion of the spring plate is located at the unlocking area of the lever, the spring plate is flatly attached to the top panel of the base, the engaging block and the cam portion are engaged and positioned, and the elastic member is in a compressed state, a fully unlocked state is formed; when the contact surface of the abutting rod is forced to push the contact portion of the spring plate upward and lift the spring plate upward, the engaging block of the spring plate is separated from the contact with the cam portion, and the elastic member forms an elastic reset state and causes the lever to rotate; when the interference portion and the locking portion of the abutting rod slightly interfere with the buffer area at the same time, a buffer unlocked state is formed; when the interference portion and the locking portion of the abutting rod are simultaneously pressed against the locking area, a fully locked state is formed. By the above, the purpose of one-time locking of the fixing device and the stepless buffer unlocking is achieved to prevent the fixing device from being damaged due to instantaneous rotation resistance stress.

Another object of the present invention is that the top panel and the bottom panel of the base are both provided with a first positioning hole; the lever further comprises a shaft hole located on the cam portion, and a pivot mounted in the shaft hole and the first positioning hole of the base to pivotally connect the lever to said base; the base further comprises a second positioning hole located on the top panel, a preset fastener selected from the group of rivets, latches and screws and fastened to the second positioning hole to fix the spring plate to the top panel, and a through hole located on the top panel for the engaging block of the spring plate to extend into and accommodate; the base further comprises a third positioning hole located on the top panel for the elastic member to extend into and fix; the elastic member is a torsion spring and comprises a ring portion sleeved on the outside of the pivot at the center thereof, a fixing end portion extended from one side of the ring portion and inserted and fixed in the third positioning hole, and a supporting end portion extended from an opposite side of the ring portion relative to the fixing end portion and positioned on one side of the operating portion of the lever.

Still another object of the present invention is that the base further comprises two fourth positioning holes respectively located on the side panels, a stopper rod mounted in the fourth positioning holes at a position vertically corresponding to the two through holes for the abutting rod to abut against, and a stop wall formed at one side of the actuating opening of the side panels adjacent to the two through holes for the operating portion of the lever to abut against; the base further comprises at least one engaging portion protruding downward from the bottom panel for being fixed in a first fixing hole of a preset first plate.

Still another object of the present invention is that the lever further comprises a protrusion formed on a top side of the cam portion, a receiving groove recessed on an inner side of the protrusion for accommodating the ring portion of the elastic member, and two engaging surfaces of the protrusion respectively formed on two opposite vertical walls of the receiving groove for the engaging block of the spring plate to engage and position.

Still another object of the present invention is that the abutment structure of the lever comprises an inclined boundary located at the center of the buffer area, and the boundary extends from the bottom side of the buffer area to the locking area to form a gradually expanding arc surface structure from top to bottom, and the inclined boundary extends from the top side of the buffer area to the unlocking area to form a vertical structure.

Still another object of the present invention is that the support further comprises an anti-rotation positioning edge cut on one side of the positioning plate, and the positioning plate with the anti-rotation positioning edge is fixed in a second fixing hole of a preset second plate; the support further comprises a positioning side formed at the abutting rod facing the stopper rod of the base, and the positioning side is selectively in a planar surface or an arc surface.

### BRIEF DESCRIPTION OF THE DRAWINGS

FIG. 1 is a three-dimensional external view of the fixing device of the present invention.

FIG. 2 is a three-dimensional exploded view of the fixing device of the present invention.

FIG. 3 is a three-dimensional exploded view of the fixing device of the present invention from another viewing angle.

FIG. 4 is a top view of the lever of the present invention.

FIG. 5 is a three-dimensional view of the fixing device of the present invention in the fully unlocked state.

FIG. 6 is a side cross-sectional view of the fixing device of the present invention in the fully unlocked state.

FIG. 7 is a side cross-sectional view of the fixing device of the present invention in the fully unlocked state from another viewing angle.

FIG. 8 is a three-dimensional view of the fixing device of the present invention in the buffer unlocked state.

FIG. 9 is a side cross-sectional view of the fixing device of the present invention in the fully locked state.

FIG. 10 is a three-dimensional external view of an application example of the fixing device of the present invention in the fully unlocked state.

FIG. 11 is a side cross-sectional view of the application example of the fixing device of the present invention in the fully unlocked state.

FIG. 12 is a side cross-sectional view of the application example of the fixing device of the present invention in the fully unlocked state from another viewing angle.

FIG. 13 is a three-dimensional external view of the application example of the fixing device of the present invention in the fully locked state.

FIG. 14 is a side cross-sectional view of the application example of the fixing device of the present invention in the fully locked state.

FIG. 15 is a side cross-sectional view of the application example of the fixing device of the present invention in the fully locked state from another viewing angle.

FIG. 16 is a structural diagram of another implementation of the support of the present invention.

### DETAILED DESCRIPTION OF THE PREFERRED EMBODIMENT

In order to achieve the above-mentioned objects and effect, the technical means and structure adopted by the present invention are described in detail with reference to the preferred embodiments of the present invention, and its features and functions are as follows for a complete understanding.

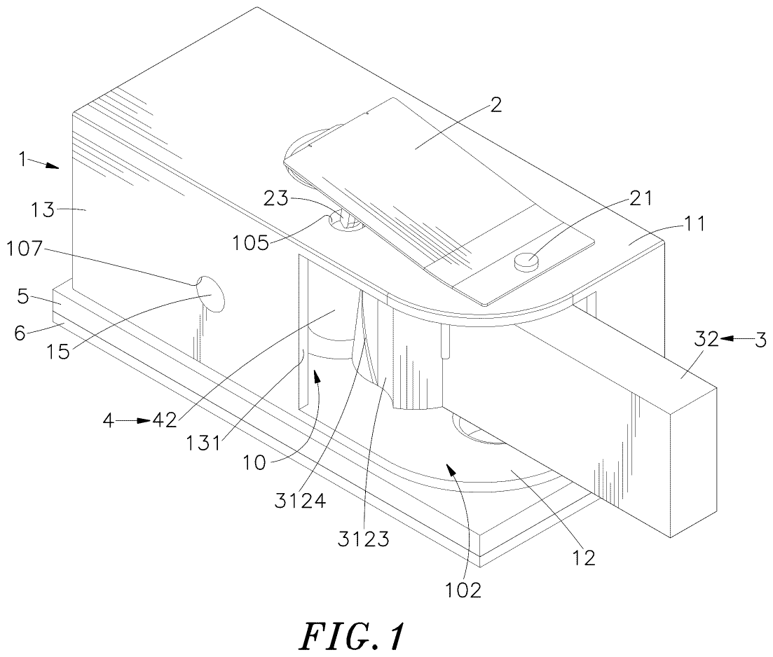

Please refer to FIGS. 1-4 and FIG. 16, which are respectively a three-dimensional external view, a three-dimensional exploded view, a three-dimensional exploded view from another viewing angle of the fixing device of the present invention, a top view of the lever, and a structural diagram of another implementation of the support of the present invention. As can be clearly seen from the figures, the fixing device of the present invention mainly comprises a base 1, a spring plate 2, a lever 3 and a support 4, and its main components and features are described in detail as follows:

The base 1 comprises a top panel 11, a bottom panel 12, two opposite side panels 13, a receiving cavity 10 surrounded by the top panel 11, the bottom panel 12 and the side panels 13, a through hole 101 provided in each of the top panel 11 and the bottom panel 12, and an actuating opening 102 formed in one side panel 13 in communication with the receiving cavity 10.

The spring plate 2 has one end thereof fixed to the top panel 11 of the base 1, an opposite end thereof provided with a contact portion 22 extending downward into the through hole 101, and an engaging block 23 extending from the bottom surface thereof into the receiving cavity 10.

The lever 3 comprises a cam portion 31 pivotally connected between the top panel 11 and the bottom panel 12 of the base 1 and received in the receiving cavity 10. An elastic member 33 is provided between the cam portion 31 and the pivoting structure of the base 1. The top side of the cam portion 31 forms a structure for the engaging block 23 of the spring plate 2 to engage and position. The cam portion 31 extends to form an operating portion 32 located at the actuating opening 102, and the cam portion 31 is formed with an abutment structure 312 on the other side thereof relative to the operating portion 32. The abutment structure 312 comprises a locking area 3121 located on one side and a buffer area 3122 located in the center, and a vertical unlocking area 3123 formed on one side of the buffer area 3122 opposite to the locking area 3121. The locking area 3121 and the buffer area 3122 are formed into a gradually expanding arc surface structure from top to bottom.

The support 4 comprises a positioning plate 41, an abutting rod 42 protruding upward from the positioning plate 41 and being capable of extending into the through hole 101 of the base 1 and entering into the receiving cavity 10, a contact surface 421 formed on the top side of the abutting rod 42, an interference portion 422 with a relatively larger width formed on an upper side of the abutting rod 42, and a locking portion 423 with a relatively smaller width formed on a lower side of the abutting rod 42. When the contact portion 22 of the spring plate 2 is located at the unlocking area 3123 of the lever 3, the spring plate 2 is flatly attached to the top panel 11 of the base 1, the engaging block 23 and the cam portion 31 are engaged and positioned, and the elastic member 33 is in a compressed state, a fully unlocked state is formed. The contact surface 421 of the abutting rod 42 can push the contact portion 22 of the spring plate 2 upward and lift the spring plate 2 upward, so that the engaging block 23 of the spring plate 2 is separated from the contact with the cam portion 31, and the elastic member 33 forms an elastic reset state and causes the lever 3 to rotate. When the interference portion 422 and the locking portion 423 of the abutting rod 42 slightly interfere with the buffer area 3122 at the same time, a buffer unlocked state is formed. When the interference portion 422 and the locking portion 423 of the abutting rod 42 are simultaneously pressed against the locking area 3121, a fully locked state is formed.

The top panel 11 and the bottom panel 12 of the base 1 are both provided with a first positioning hole 103 for a pivot 14 at the cam portion 31 to pass through and fix, and the cam portion 31 is provided with a shaft hole 310 for the pivot 14 to pass through. The top panel 11 of the base 1 is provided with a second positioning hole 104 for fixing the spring plate 2 with a preset fastener 21. The preset fastener 21 is a rivet, a latch or a screw. The top panel 11 is provided with a through hole 105 for the engaging block 23 of the spring plate 2 to extend into and accommodate.

The top panel 11 of the base 1 is provided with a third positioning hole 106 for the elastic member 33 to extend into and fix. The elastic member 33 comprises a ring portion 332 sleeved on the outside of the pivot 14 at the center thereof, a fixing end portion 331 extended from one side of the ring portion 332 and inserted and fixed in the third positioning hole 106 on the top panel 11 of the base 1, and a supporting end portion 333 extended from an opposite side of the ring portion 332 relative to the fixing end portion 331 and positioned on one side of the operating portion 32 of the lever 3. The elastic member 33 is a torsion spring.

The side panels 13 of the base 1 are respectively provided with a fourth positioning hole 107 for a stopper rod 15 to pass through at a position vertically corresponding to the two through holes 101. The stopper rod 15 can be used for the abutting rod 42 to abut against the side. The actuating opening 102 of the side panel 13 is formed with a stop wall 131 adjacent to the two through holes 101 for the operating portion 32 of the lever 3 to abut against. The bottom panel 12 of the base 1 is provided with at least one engaging portion 121 protruding downward for being fixed in a first fixing hole 51 of a preset first plate 5.

A protrusion 311 is formed on the top side of the cam portion 31 of the lever 3, and the inner side of the protrusion 311 is recessed to form a receiving groove 3111 for accommodating the ring portion 332 of the elastic member 33, and the protrusion 311 has engaging surfaces 3112 formed on the vertical walls on both sides of the receiving groove 3111 for the engaging block 23 of the spring plate 2 to engage and position.

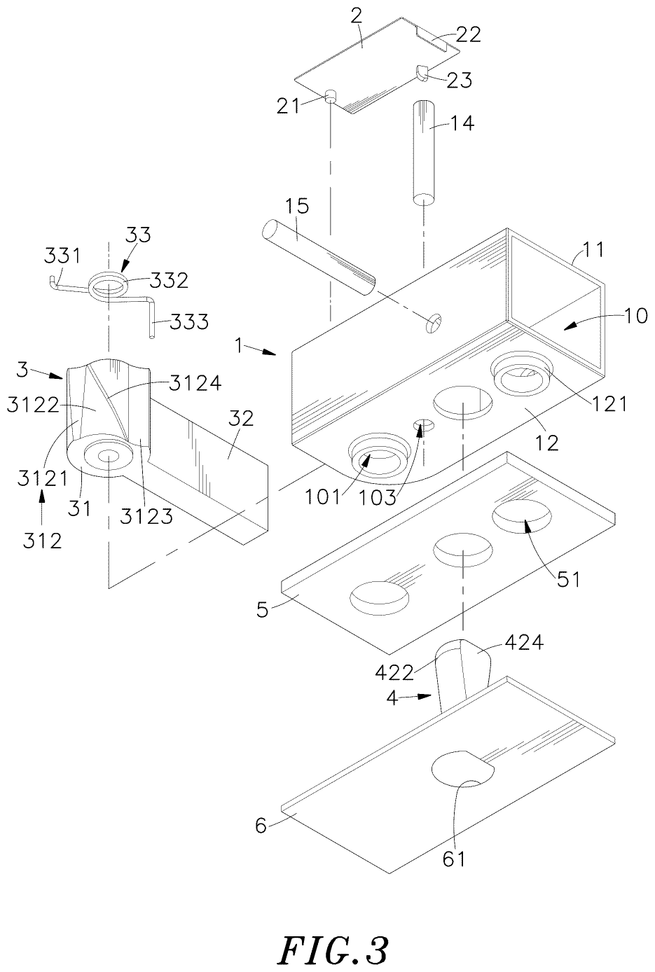

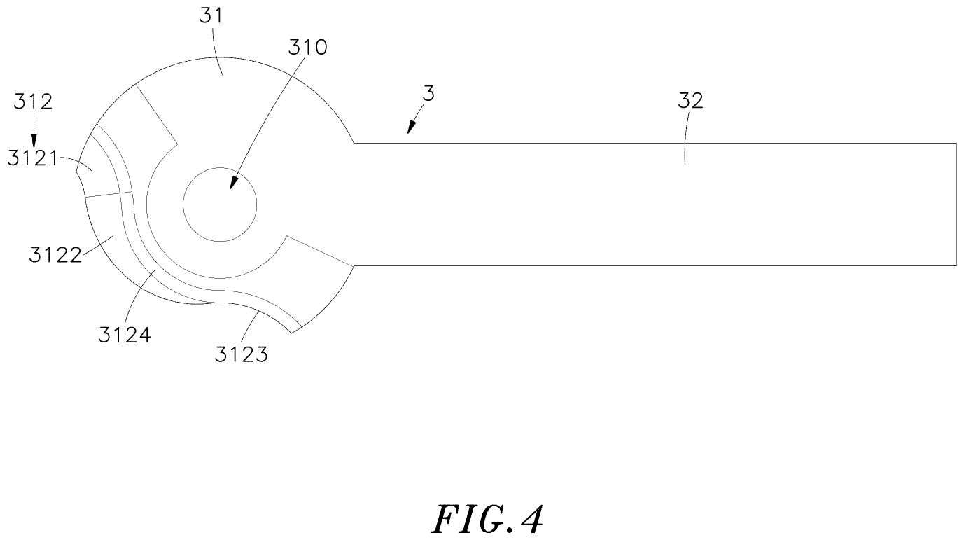

Please refer to FIGS. 3 and 4, in which the abutment structure 312 of the lever 3 comprises an inclined boundary 3124 located at the center of the buffer area 3122, and the boundary 3124 extends from the bottom side of the buffer area 3122 to the locking area 3121 to form a gradually expanding arc surface or a gradually expanding slope surface (not shown in the figure) structure from top to bottom. The lower part of the buffer area 3122 is only at a relatively long distance from the shaft hole 310 at the center of the cam portion 31, so as to form slight interference state with the tapered abutting rod 42. The upper and lower parts of the locking area 3121 are at a relatively long distance from the shaft hole 310 at the center of the cam portion 31, so as to form a tight interference state with the tapered abutting rod 42. The boundary 3124 extends from the top side of the buffer area 3122 to the unlocking area 3123 to form a vertical structure, and the upper and lower parts of the unlocking area 3123 are close to the shaft hole 310 at the center of the cam portion 31, so as to form a non-interference state with the tapered abutting rod 42.

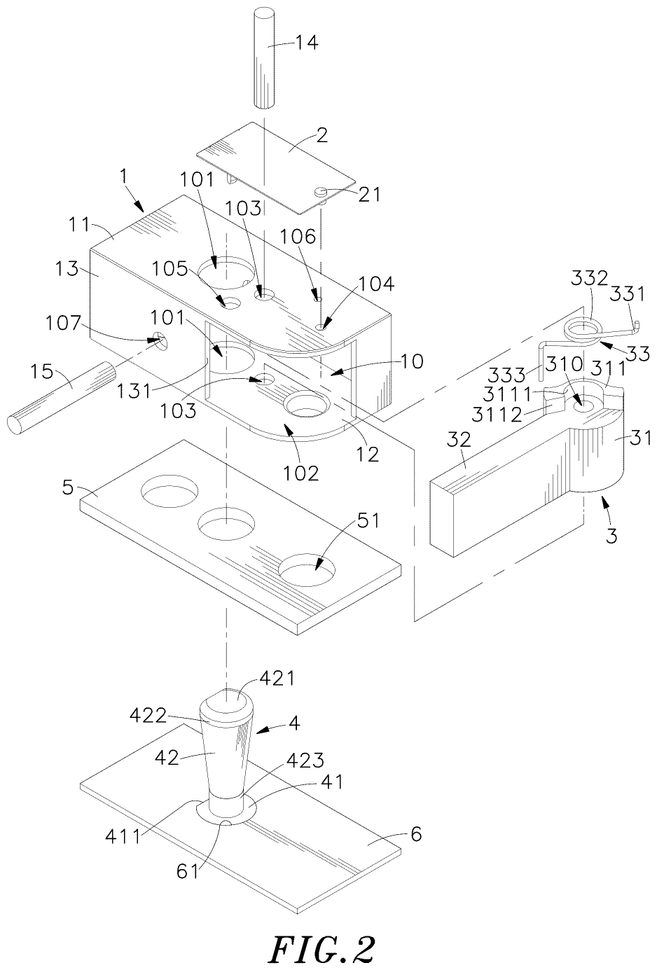

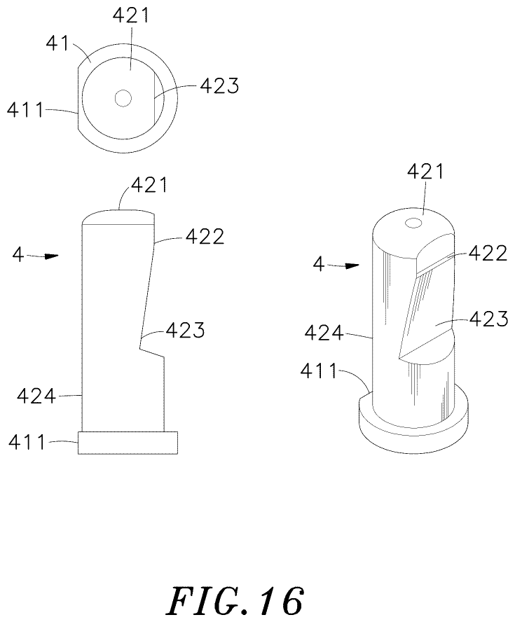

An anti-rotation positioning edge 411 is cut on one side of the positioning plate 41 of the support 4, and the positioning plate 41 with the anti-rotation positioning edge 411 is fixed in a second fixing hole 61 of a preset second plate 6. The abutting rod 42 of the support 4 is formed with a positioning side 424 on one side thereof corresponding to the stopper rod 15 of the base 1. The positioning side 424 is in a planar shape (as shown in FIG. 3) or an arc shape (as shown in FIG. 16). The abutting rod 42 which is wide at the top or narrow at the bottom contacts the lever 3 and has an abutment structure 312 which is a gradually expanding arc surface or a gradually expanding slope surface. It can also be a gradually contracting arc surface (as shown in FIG. 2) or a gradually contracting slope surface (as shown in FIG. 16).

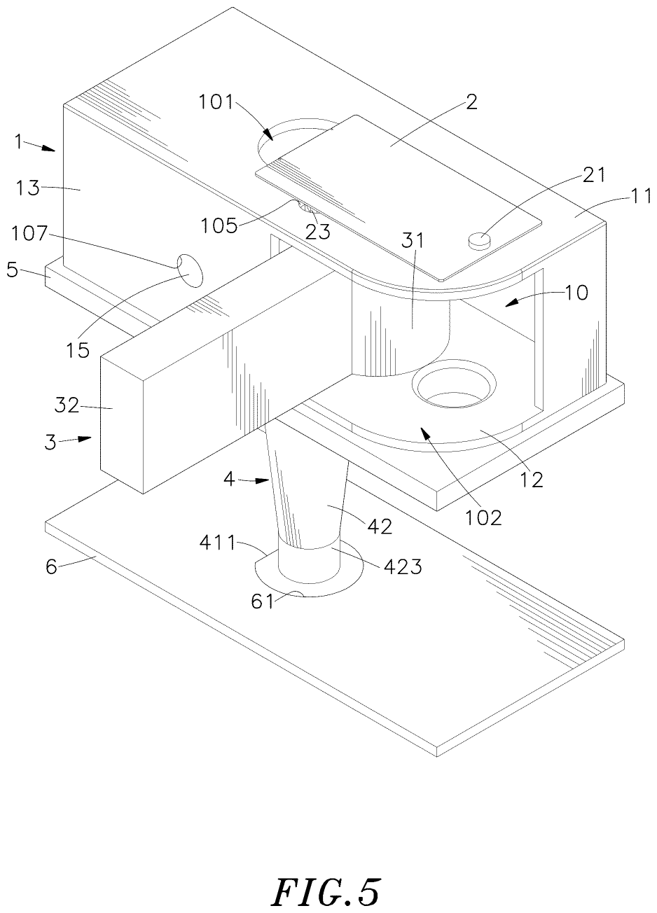

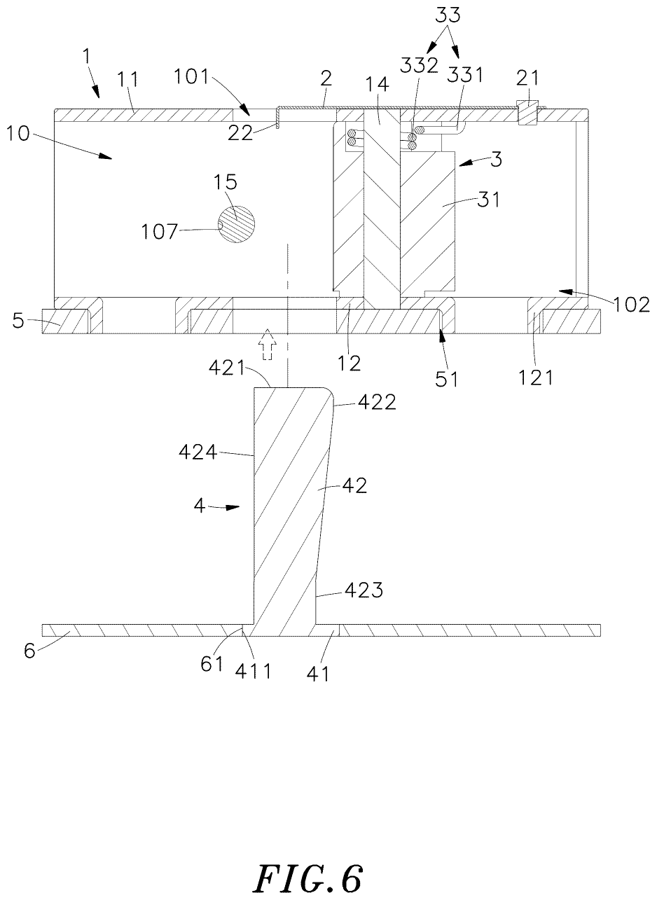

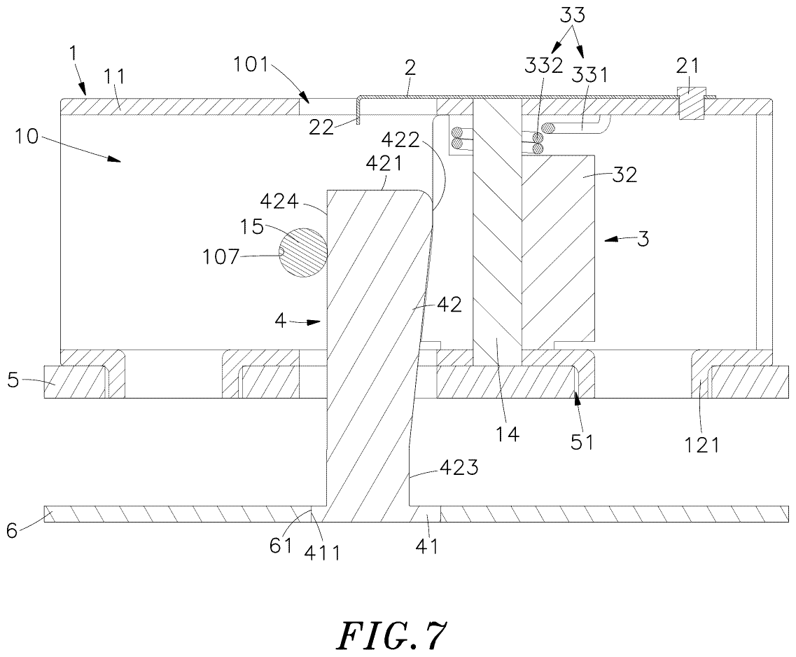

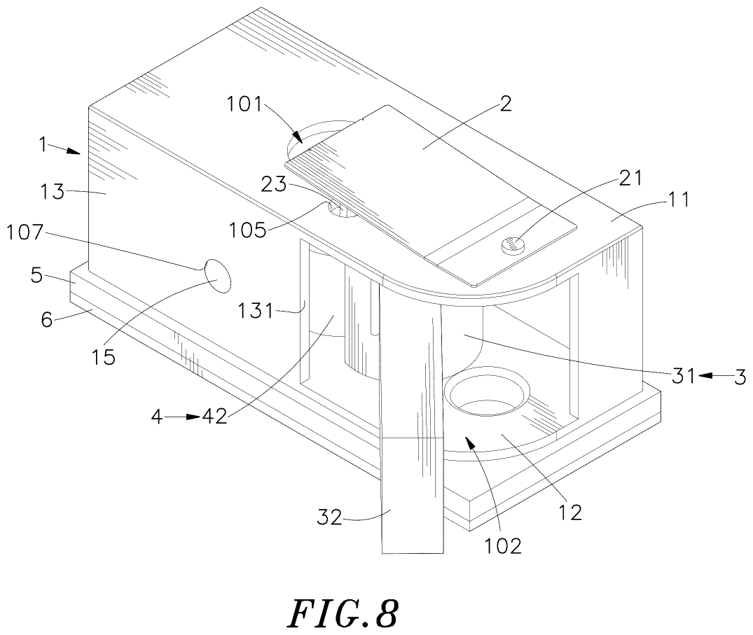

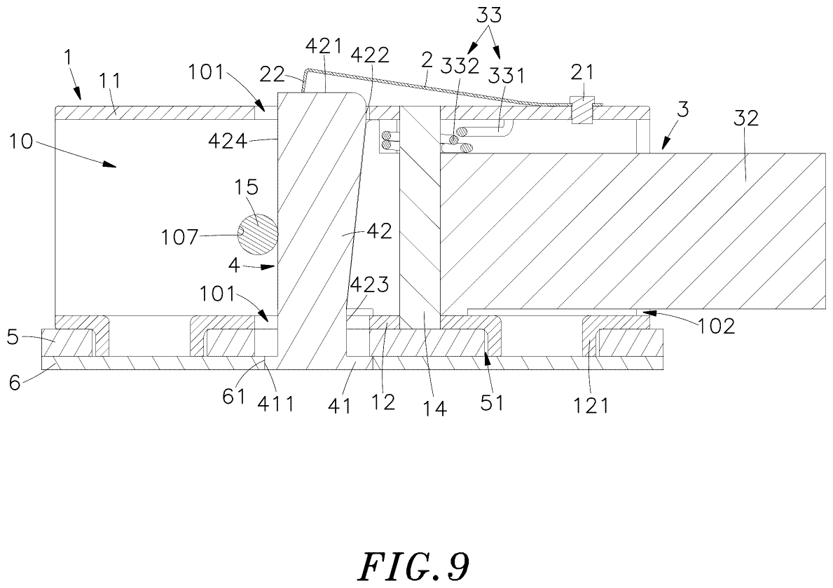

Please refer to FIGS. 5 to 7, which are a three-dimensional view, a side cross-sectional view, and a side cross-sectional view from another viewing angle of the fixing device of the present invention in the fully unlocked state, which discloses that the base 1, the spring plate 2, and the lever 3 are fixed on the first plate 5, and the support 4 is fixed on the second plate 6, and when the operating portion 32 of the lever 3 is approximately perpendicular to the base 1 and forms a contact with the stop wall 131 of the base 1, and the elastic member 33 is in a compressed state, a fully unlocked state of the fixing device is formed. Please refer to FIG. 8, which is a three-dimensional view of the fixing device of the present invention in the buffer unlocked state. When the first plate 5 is moved downward close to the second plate 6 by force, the abutting rod 42 of the support 4 extends into the through hole 101 of the base 1 and enters the receiving cavity 10, the contact surface 421 of the abutting rod 42 can push the contact portion 22 of the spring plate 2 upward and lift the spring plate 2 upward, so that the engaging block 23 of the spring plate 2 is separated from the contact with the cam portion 31, the elastic member 33 forms an elastic return state and causes the lever 3 to rotate, and the operating portion 32 of the lever 3 is in an inclined state at an angle of 1 to 89 degrees with the base 1, and the interference portion 422 and the locking portion 423 of the abutting rod 42 slightly interfere with the buffer area 3122 to form a buffer unlocked state, so that the rotational holding stress generated by the lever 3 during the locking process can be buffered and the overall damage of the fixing device can be effectively avoided. Please refer to FIG. 9, which is a side cross-sectional view of the fixing device of the present invention in the fully locked state. When the lever 3 is subjected to the elastic restoring force of the elastic member 33 and continues to rotate, the interference portion 422 and the locking portion 423 of the abutting rod 42 are simultaneously pressed against the locking area 3121 to form a tight interference, and the operating portion 32 of the lever 3 is approximately parallel to the base 1 to form a fully locked state, so that the first plate 5 and the second plate 6 can form a combined fixed structure.

When the first plate 5 and the second plate 6 are to be separated and disassembled, it is only necessary to apply force to the operating portion 32 of the lever 3 which is approximately parallel to the base 1, and rotate it from the parallel angle to the vertical direction, so that the contact positions of the abutment structure 312 of the lever 3 and the interference portion 422 and the locking portion 423 of the abutting rod 42 are arranged in the order of the locking area 3121, the buffer area 3122 and the unlocking area 3123. After the unlocking area 3123 are not in contact with the interference portion 422 and the locking portion 423 of the abutting rod 42, force is applied to the first plate 5 to move upward and away from the second plate 6 and to disengage the abutting rod 42 of the support 4 from the through hole 101 of the base 1. When the operating portion 32 of the lever 3 is approximately perpendicular to the base 1, the elastic member 33 is in a compressed state. At the same time, the engaging block 23 of the spring plate 2 generates a restoring force to engage and position with the engaging surfaces 3112 of the lever 3 downward. Through the above operation, the first plate 5 and the second plate 6 are separated and disassembled.

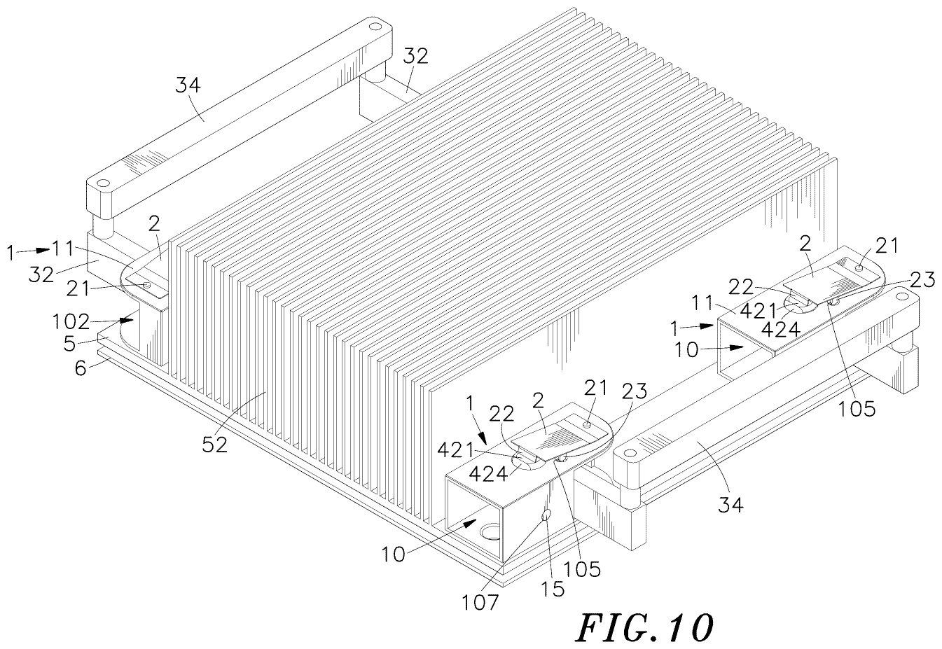

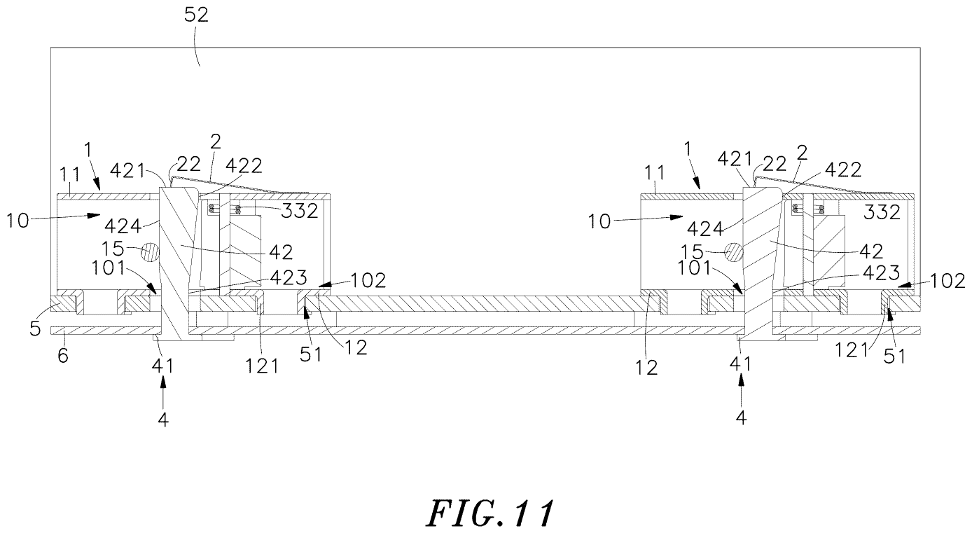

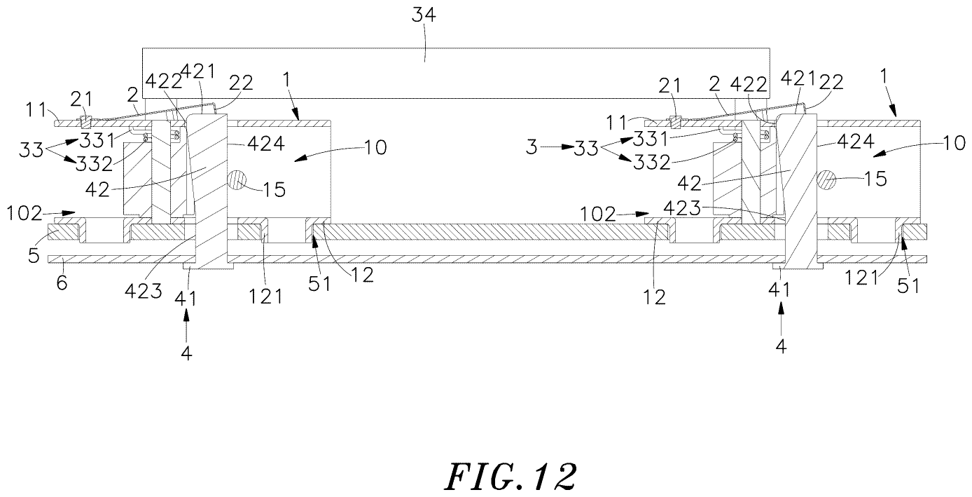

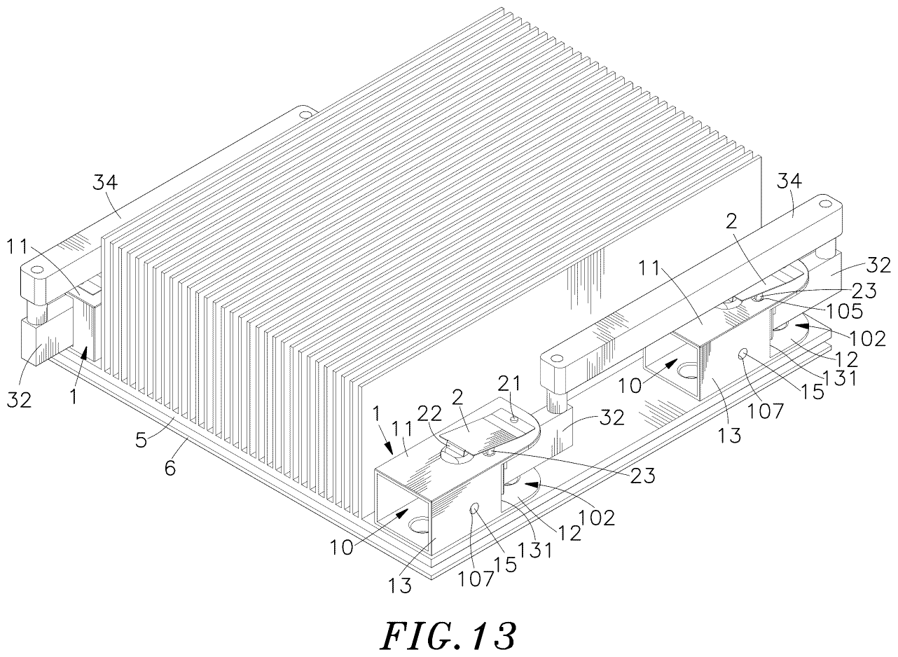

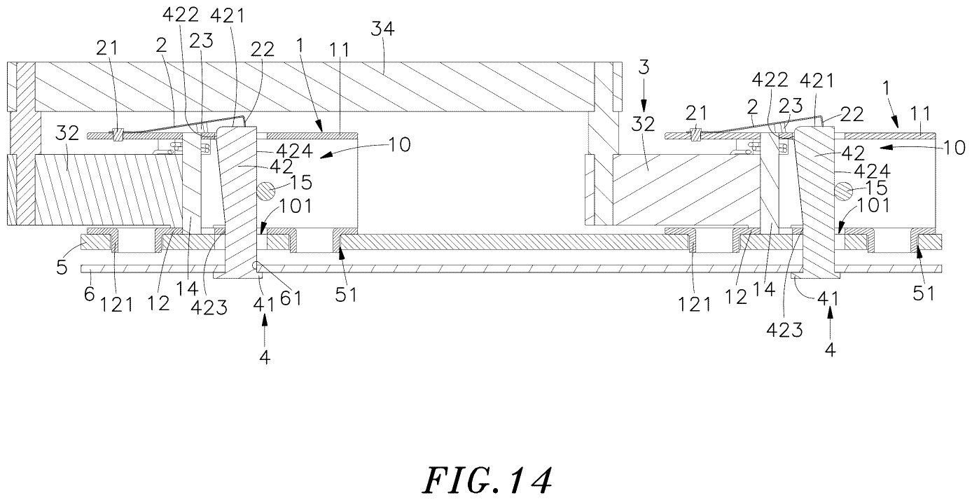

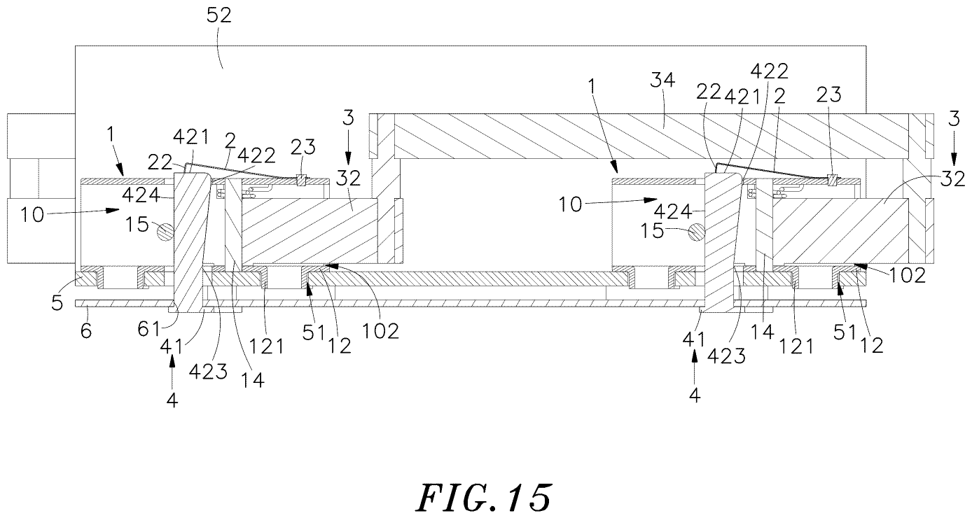

Please refer to FIGS. 10 to 15, which are a three-dimensional external view, a side cross-sectional view, and a side cross-sectional view from another viewing angle of an application example of the fixing device of the present invention in the fully unlocked state; a three-dimensional external view, a side cross-sectional view, and a side cross-sectional view from another viewing angle of the application example of the fixing device of the present invention in the fully locked state, wherein the first plate 5 assembled on the bottom side of the base 1, the spring plate 2, and the lever 3 of the fixing device refers to a metal plate installed on the edge of a heat sink 52 on the surface of an electronic component that is prone to generate high temperature (such as a central processing unit (CPU), a graphics processing unit (GPU), a microcontroller unit (MCU), or a power supply component). The second plate 6 assembled on the bottom side of the support 4 refers to the metal plate fixed to the edge of a socket (not shown in the figure) of a high-temperature electronic component on a printed circuit board (PCB). When the first plate 5 at the edge of the heat sink 52 is provided with four combined structure of bases 1, spring plates 2 and levers 3 and the second plate 6 at the edge of the socket is provided with four supports 4, and the four levers 3 are set in two groups and each group is provided with a connecting rod 34 for linkage. When the four levers 3 connected to the two connecting rods 34 are all at an approximately vertical angle with the base 1, the fully unlocked state is formed. When the two connecting rods 34 are rotated in the horizontal direction and the four levers 3 are all approximately parallel to the base 1, the fully locked state is formed. When the two connecting rods 34 rotate in the horizontal direction, the four levers 3 are all at an angle of 1 to 89 degrees with the base 1, the buffer unlocked state is formed. Through the above-mentioned embodiments, the heat sink 52 and the socket on the circuit board can be quickly assembled and disassembled and the stepless buffer unlocking operation can be realized.

The main features of the present invention are that when the contact portion 22 of the spring plate 2 of the fixing device and the unlocking area 3123 of the lever 3 do not contact the abutting rod 42, the spring plate 2 is flatly attached to the top panel 11 of the base 1, the engaging block 23 and the cam portion 31 are locked and positioned, and the elastic member 33 is in a compressed state, the fully unlocked state is formed; the contact surface 421 of the abutting rod 42 can push the contact portion 22 of the spring plate 2 upward and lift the spring plate 2 upward, so that the engaging block 23 of the spring plate 2 is separated from the contact with the cam portion 31, the elastic member 33 forms an elastic reset state and causes the lever 3 to rotate, so that the interference portion 422 and the locking portion 423 of the abutting rod 42 slightly interfere with the buffer area 3122 at the same time to form the buffer unlocked state; when the interference portion 422 and the locking portion 423 of the abutting rod 42 are simultaneously pressed against the locking area 3121, the fully locked state is formed. By the above, the purpose of one-time locking of the fixing device and the stepless buffer unlocking is achieved to prevent the fixing device from being damaged due to instantaneous rotation resistance stress.

The above are only preferred embodiments of the present invention, and do not limit the patent scope of the present invention. Therefore, all simple modifications and equivalent structural changes made by using the contents of the description and drawings of the present invention should be included in the patent scope of the present invention and should be declared.

In summary, the automatic positioning and stepless unlocking fixing device of the present invention can achieve its effect and purpose when used. Therefore, this invention is truly an invention with excellent practicality. In order to meet the application requirements for invention patents, we have filed an application in accordance with the law. We hope that the review committee will approve this case as soon as possible to protect the inventor's hard work in research and development. If the review committee has any questions, please feel free to write to us for instructions. The inventor will do his best to cooperate and we will be very grateful.

What the invention claimed is:

1. An automatic positioning and stepless unlocking fixing device, comprising
a base comprising a top panel, a bottom panel, two opposite side panels, a receiving cavity surrounded by said top panel, said bottom panel and said side panels, a through hole provided in each of said top panel and said bottom panel, and an actuating opening formed in one said side panel in communication with said receiving cavity;
a spring plate with one end thereof fixed to said top panel of said base, said spring plate comprising a contact portion located at an opposite end thereof and extending downward into said through hole and an engaging block extending from a bottom surface thereof into said receiving cavity;
a lever comprising a cam portion pivotally connected between said top panel and said bottom panel of said base and received in said receiving cavity, an elastic member provided between said cam portion and a part of said base pivoting with said cam portion, a structure formed on a top side of said cam portion for said engaging block of said spring plate to engage and position, an operating portion extending from said cam portion and located at said actuating opening and an abutment structure formed on an opposite side of said cam portion relative to said operating portion, said abutment structure comprising a locking area located on one side, a buffer area located in the center and a vertical unlocking area formed on one side of said buffer area opposite to said locking area, said locking area and said buffer area being formed into a gradually expanding arc surface structure from top to bottom; and
a support comprising a positioning plate, an abutting rod protruding upward from said positioning plate and being capable of extending into said through hole of said base and entering into said receiving cavity, a contact surface formed on a top side of said abutting rod, an interference portion with a relatively larger width formed on an upper side of said abutting rod and a locking portion with a relatively smaller width formed on a lower side of said abutting rod; and
wherein when said contact portion of said spring plate is located at said unlocking area of said lever, said spring plate is flatly attached to said top panel of said base, said engaging block and said cam portion are engaged and positioned, and said elastic member is in a compressed state, a fully unlocked state is formed; when said contact surface of said abutting rod is forced to push said contact portion of said spring plate upward and lift said spring plate upward, said engaging block of said spring plate is separated from the contact with said cam portion, and said elastic member forms an elastic reset state and causes said lever to rotate; when said interference portion and said locking portion of said abutting rod slightly interfere with said buffer area at the same time, a buffer unlocked state is formed; when said interference portion and said locking portion of said abutting rod are simultaneously pressed against said locking area, a fully locked state is formed.

2. The automatic positioning and stepless unlocking fixing device as claimed in claim 1, wherein said top panel and said bottom panel of said base are both provided with a first positioning hole; said lever further comprises a shaft hole located on said cam portion, and a pivot mounted in said shaft hole and said first positioning hole of said base to pivotally connect said lever to said base.

3. The automatic positioning and stepless unlocking fixing device as claimed in claim 1, wherein said base further comprises a second positioning hole located on said top panel, a preset fastener selected from the group of rivets, latches and screws and fastened to said second positioning hole to fix said spring plate to said top panel, and a through hole located on said top panel for said engaging block of said spring plate to extend into and accommodate.

4. The automatic positioning and stepless unlocking fixing device as claimed in claim 1, wherein said base further comprises a third positioning hole located on said top panel for said elastic member to extend into and fix; said elastic member is a torsion spring and comprises a ring portion sleeved on the outside of said pivot at the center thereof, a fixing end portion extended from one side of said ring portion and inserted and fixed in said third positioning hole, and a supporting end portion extended from an opposite side of said ring portion relative to said fixing end portion and positioned on one side of said operating portion of said lever.

5. The automatic positioning and stepless unlocking fixing device as claimed in claim 1, wherein said base further comprises two fourth positioning holes respectively located on said side panels, a stopper rod mounted in said fourth positioning holes at a position vertically corresponding to two said through holes for said abutting rod to abut against, and a stop wall formed at one side of said actuating opening of said side panels adjacent to two said through holes for said operating portion of said lever to abut against.

6. The automatic positioning and stepless unlocking fixing device as claimed in claim 1, wherein said base further comprises at least one engaging portion protruding downward from said bottom panel for being fixed in a first fixing hole of a preset first plate.

7. The automatic positioning and stepless unlocking fixing device as claimed in claim 1, wherein said lever further comprises a protrusion formed on a top side of said cam portion, a receiving groove recessed on an inner side of said protrusion for accommodating said ring portion of said elastic member, and two engaging surfaces of said protrusion respectively formed on two opposite vertical walls of said receiving groove for said engaging block of said spring plate to engage and position.

8. The automatic positioning and stepless unlocking fixing device as claimed in claim 1, wherein said abutment structure of said lever comprises an inclined boundary located at the center of said buffer area, said boundary extending from a bottom side of said buffer area to said locking area to form a gradually expanding arc surface structure from top to bottom, said boundary extending from a top side of said buffer area to said unlocking area to form a vertical structure.

9. The automatic positioning and stepless unlocking fixing device as claimed in claim 1, wherein said support further comprises an anti-rotation positioning edge cut on one side of said positioning plate, and said positioning plate with said anti-rotation positioning edge is fixed in a second fixing hole of a preset second plate.

10. The automatic positioning and stepless unlocking fixing device as claimed in claim 1, wherein said support further comprises a positioning side formed at said abutting rod facing said stopper rod of said base, said positioning side being selectively in a planar surface or an arc surface.
